(19) United States
(12) Patent Application Publication
(10) Pub. No.: US 2026/0144025 A1
(43) Pub. Date: May 21, 2026

(54) METHOD FOR MANUFACTURING SEMICONDUCTOR DEVICE

(71) Applicant: Kioxia Corporation, Tokyo (JP)

(72) Inventor: Toshiaki YANASE, Yokkaichi (JP)

(73) Assignee: Kioxia Corporation, Tokyo (JP)

(21) Appl. No.: 19/079,713

(22) Filed: Mar. 14, 2025

(30) Foreign Application Priority Data
Nov. 18, 2024 (JP) 2024-201176

(51) Int. Cl. H01L 21/78; H01L 23/00; H10B 80/00

(52) U.S. Cl. CPC H10P 95/112; H10B 80/00; H10W 80/327

(57) ABSTRACT

A method for manufacturing a semiconductor device forms a first semiconductor wafer including a main body and a silicon film. The main body has a Young's modulus higher than silicon and includes a side surface between a first surface and a second surface opposite to the first surface. The first silicon film is formed at the first surface, the second surface, and the side surface of the wafer main body. A first circuit and a first insulation layer covering the first circuit are formed on the first surface of the first semiconductor wafer. A second circuit is formed on a second semiconductor wafer. A second insulation layer covering the second circuit is formed on the second semiconductor wafer. The first circuit and the second circuit are opposed to each other and the first insulation layer and the second insulation layer are bonded and then the first semiconductor wafer is removed.

### CROSS-REFERENCE TO RELATED APPLICATION(S)

This application is based upon and claims the benefit of priority from Japanese Patent Application No. 2024-201176, filed Nov. 18, 2024, the entire contents of which are incorporated herein by reference.

### FIELD

Embodiments described herein relate generally to a method for manufacturing a semiconductor device.

### BACKGROUND

In a manufacturing process for a semiconductor device, the warpage of semiconductor wafer increases as a device layer formed on the semiconductor wafer becomes thicker.

### DESCRIPTION OF THE DRAWINGS

FIG. 1 is a cross-sectional view illustrating an example of a manufacturing method for a semiconductor device according to a first embodiment.

FIG. 2 is a cross-sectional view illustrating the example of the manufacturing method, subsequent to FIG. 1.

FIG. 3 is a cross-sectional view illustrating the example of the manufacturing method, subsequent to FIG. 2.

FIG. 4 is a cross-sectional view illustrating the example of the manufacturing method, subsequent to FIG. 3.

FIG. 5 is a cross-sectional view illustrating the example of the manufacturing method, subsequent to FIG. 4.

FIG. 6 is a cross-sectional view illustrating the example of the manufacturing method, subsequent to FIG. 5.

FIG. 7 is a cross-sectional view illustrating the example of the manufacturing method, subsequent to FIG. 6.

FIG. 8 is a cross-sectional view illustrating the example of the manufacturing method, subsequent to FIG. 7.

FIG. 9 is a graph showing the relationship between the number of layers stacked in a memory cell array and the amount of warpage of a semiconductor wafer.

FIG. 10 is a cross-sectional view illustrating an example of a manufacturing method for a memory device according to the present embodiment.

FIG. 11 is a cross-sectional view illustrating the example of the manufacturing method, subsequent to FIG. 10.

FIG. 12 is a cross-sectional view illustrating the example of the manufacturing method, subsequent to FIG. 11.

FIG. 13 is an enlarged cross-sectional view of a memory pillar of FIG. 12.

FIG. 14 is a cross-sectional view illustrating the example of the manufacturing method, subsequent to FIG. 12.

FIG. 15 is a cross-sectional view illustrating the example of the manufacturing method, subsequent to FIG. 14.

FIG. 16 is a cross-sectional view illustrating the example of the manufacturing method, subsequent to FIG. 15.

FIG. 17 is a cross-sectional view illustrating the example of the manufacturing method, subsequent to FIG. 16.

FIG. 18 is a cross-sectional view illustrating the example of the manufacturing method, subsequent to FIG. 17.

### DETAILED DESCRIPTION

In general, according to one embodiment, a method for manufacturing a semiconductor device forms, a first semiconductor wafer including a first wafer main body and a first silicon film, the first wafer main body including a first surface, a second surface located opposite to the first surface, and a side surface located between the first surface and the second surface, the first wafer main body having a Young's modulus higher than silicon, the first silicon film being formed at the first surface, the second surface, and the side surface of the first wafer main body. A first circuit is formed on the first surface of the first semiconductor wafer. A first insulation layer covering the first circuit is formed on the first surface of the first semiconductor wafer. A second circuit is formed on a second semiconductor wafer. A second insulation layer covering the second circuit is formed on the second semiconductor wafer. The first circuit and the second circuit are opposed to each other and the first insulation layer and the second insulation layer are bonded. After bonding the first insulation layer and the second insulation layer, the first semiconductor wafer is removed.

Embodiments will be described below with reference to the accompanying drawings. The embodiments will not limit the present disclosure. The drawings are schematic or conceptual. In the specification and the drawings, the same elements are denoted by the same reference signs.

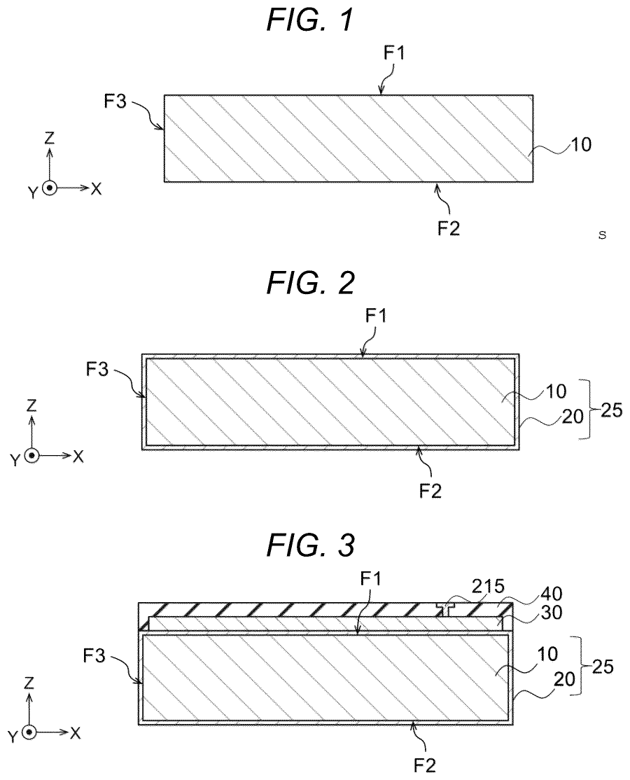

FIG. 1 to FIG. 8 are cross-sectional views illustrating an example of a manufacturing method for a semiconductor device according to the present embodiment. The semiconductor device may be, for example, a NAND flash memory, but may be any other semiconductor device. The embodiment is a manufacturing method for a semiconductor device in which a first semiconductor element formed on a first semiconductor wafer and a second semiconductor element formed on a second semiconductor wafer are bonded together and electrically connected to each other. The first semiconductor element may be, for example, a three-dimensional memory cell array made by arranging memory cells three-dimensionally. The second semiconductor element may be, for example, a complementary metal oxide semiconductor (CMOS) circuit that controls the first semiconductor element. The first and second semiconductor elements are not limited thereto.

First, a wafer main body 10 is prepared as illustrated in FIG. 1. The wafer main body 10 includes a first surface F1 at which a semiconductor element is to be formed, a second surface F2 located opposite to the first surface F1, and a side surface F3 located between the first surface F1 and the second surface F2.

The wafer main body 10 is made of a material having Young's modulus higher than silicon. The wafer main body 10 is made of a material containing, for example, SiC, Si₃N₄, AlN, Al₂O₃, or diamond. The Young's modulus of silicon is about 131 gigapascal (GPa). On the other hand, the Young's modulus of SiC is about 410 GPa, the Young's modulus of Si₃N₄ is about 300 GPa, the Young's modulus of AlN is about 320 GPa, the Young's modulus of Al₂O₃ is about 400 Gpa, and the Young's modulus of diamond is about 1050 GPa. Thus, when the wafer main body 10 is made of a material containing SiC, Si₃N₄, AlN, Al₂O₃, or diamond, the Young's modulus of the wafer main body 10 becomes higher than that of silicon. Considering the magnitude of Young's modulus and cost, the wafer main body 10 is preferably made of SiC.

A silicon film 20 is formed at a front surface of the wafer main body 10 as illustrated in FIG. 2. As a result, a semiconductor wafer 25 as a first semiconductor wafer is formed. The silicon film 20 is formed not only at the first surface F1 of the wafer main body 10 at which the semiconductor element is formed, but also at the second surface F2 and the side surface F3. Preferably, the silicon film 20 continuously covers the first surface, the second surface, and the side surface F1 to F3 of the wafer main body 10 without exposing the wafer main body 10 from the silicon film 20.

For example, if the silicon film 20 is formed only at a part of the front surface of the wafer main body 10, an etching solution or the like may enter an interface between the silicon film 20 and the wafer main body 10 from an edge portion of the silicon film 20. In that case, the edge portion of the silicon film 20 is etched to be processed into an undesirable shape, for example, an eave-like shape.

On the other hand, when the silicon film 20 continuously covers the first surface, the second surface, and the side surface F1 to F3 of the wafer main body 10, edge portions of the silicon film 20 no longer exist, and thus the etching solution can be prevented from entering the interface between the silicon film 20 and the wafer main body 10. As a result, deformation of the silicon film 20 can be prevented.

Since the silicon film 20 covers the first surface F1 of the wafer main body 10, even when the first surface F1 of the wafer main body 10 is defective, the silicon film 20 flattens the first surface F1. For example, even when the wafer main body 10 is made of a polycrystalline material (e.g., polycrystalline SiC), the silicon film 20 covers defects and irregularities in the first surface F1 of the wafer main body 10 and the first surface F1 is flattened. As a result, the surface of the semiconductor wafer 25 on the first surface F1 side becomes flat, and the semiconductor element can be formed on the first surface F1 of the semiconductor wafer 25 as designed.

There is a negative correlation between Young's modulus and friction coefficient, and the higher the Young's modulus is, the higher the wear resistance and the smaller the friction coefficient are. Thus, silicon has a larger friction coefficient than SiC, Si₃N₄, AlN, Al₂O₃, or diamond. Accordingly, by providing the silicon film 20 at the second surface F2 of the wafer main body 10, the semiconductor wafer 25 becomes less likely to slip on a stage or a tray during a manufacturing process and transportation. Thus, the position of the semiconductor wafer 25 becomes less likely to be displaced during the manufacturing process. In addition, the semiconductor wafer 25 becomes less likely to fall during conveyance.

Further, the silicon film 20 continuously covers the wafer main body 10, thereby protecting the wafer main body 10. Accordingly, the wafer main body 10 is less likely to be damaged, and thus the wafer main body 10 can be easily reused after the semiconductor wafer 25 is separated from the semiconductor element.

Next, as illustrated in FIG. 3, a semiconductor element 30 is formed on the semiconductor wafer 25. As described above, the semiconductor element 30 as the first semiconductor element may be, for example, a memory cell array of a NAND flash memory. A process of forming the memory cell array will be described below.

Next, as illustrated in FIG. 3, an insulation layer 40 is formed on the semiconductor wafer 25 to cover the semiconductor element 30. The insulation layer 40 as the first insulation layer may be, for example, a silicon oxide film formed using tetraethoxysilane (TEOS).

Next, a via contact and wiring 215 are formed inside the insulation layer 40. The wiring 215 is electrically connected to any part of the semiconductor element 30 and is exposed at a front surface of the insulation layer 40.

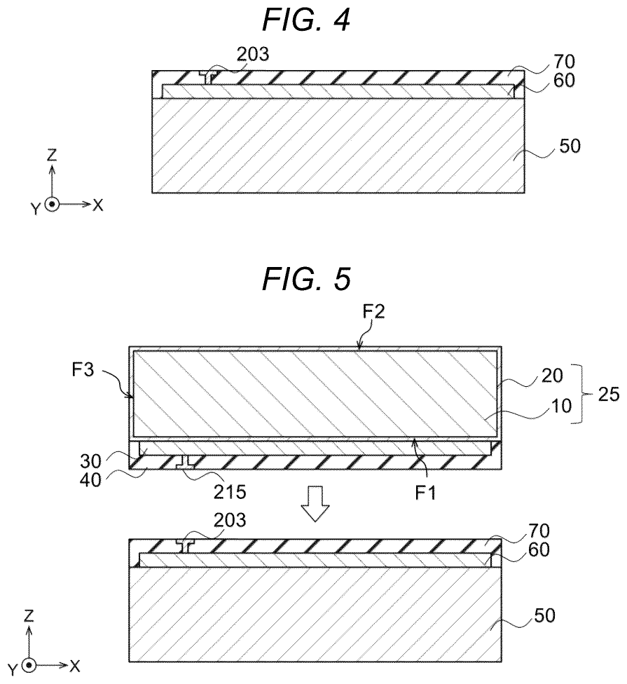

Next, as illustrated in FIG. 4, a semiconductor element 60 is formed on a semiconductor wafer 50 as the second semiconductor wafer. The semiconductor wafer 50 may be, for example, a semiconductor substrate such as a silicon substrate. As described above, the semiconductor element 60 as the second semiconductor element may be, for example, a CMOS circuit.

Similar to the semiconductor wafer 25, the semiconductor wafer 50 may have a configuration in which the wafer main body 10 is covered with the silicon film 20.

Next, an insulation layer 70 is formed on the semiconductor wafer 50 to cover the semiconductor element 60. The insulation layer 70 as the second insulation layer may be, for example, a silicon oxide film formed using TEOS.

Next, a via contact and wiring 203 are formed inside the insulation layer 70. The wiring 203 is electrically connected to any part of the semiconductor element 60 and is exposed at the front surface of the insulation layer 70.

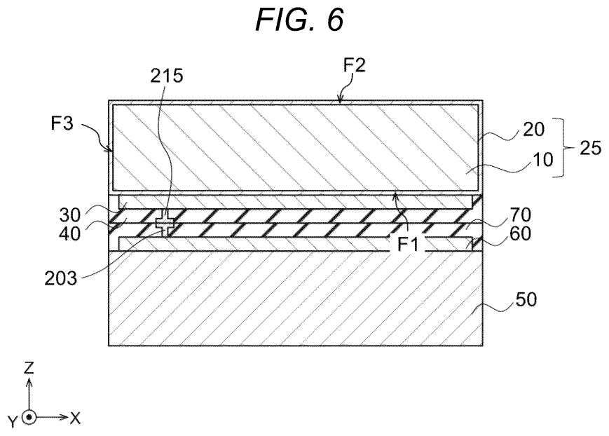

Next, the semiconductor wafer 25 or 50 is turned upside down to cause the semiconductor element 30 and the semiconductor element 60 to be opposed to each other as illustrated in FIG. 5, and the insulation layer 40 and the insulation layer 70 are bonded together. At this time, as illustrated in FIG. 6, the wiring 203 and the wiring 215 are brought into contact with each other to be electrically connected to each other.

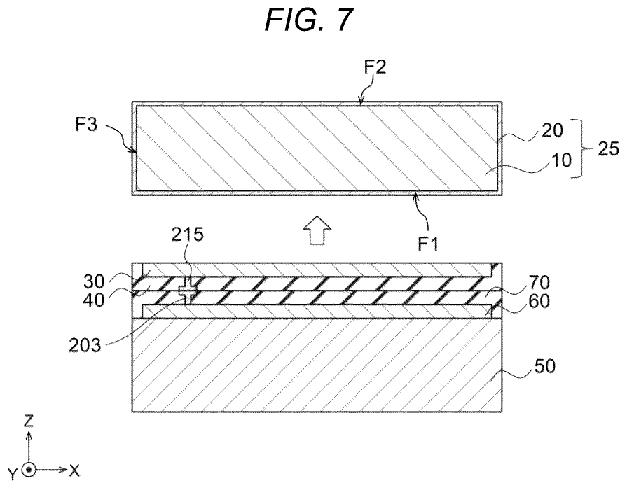

Next, as illustrated in FIG. 7, the semiconductor wafer 25 is separated and removed from the semiconductor element 30 and the insulation layer 70. At this time, the semiconductor wafer 25 may be separated using wet etching, or a laser separation method, a separation method using a blade, or a separation method using waterjet may also be used. For example, in the wet etching, the silicon film 20 of the semiconductor wafer 25 is etched with a chemical solution, thereby separating the semiconductor wafer 25 from the semiconductor element 30. In the laser separation method, by irradiating an interface between the semiconductor wafer 25 and the semiconductor element 30 with a laser beam, the silicon film 20 is heated and expanded, and the semiconductor wafer 25 is separated from the semiconductor element 30 at the interface. In the separation method using a blade, the blade is inserted into an interface between the semiconductor wafer 25 and the semiconductor element 30, thereby separating the semiconductor wafer 25 from the semiconductor element 30. In the separation method using waterjet, the waterjet is applied to an interface between the semiconductor wafer 25 and the semiconductor element 30, thereby separating the semiconductor wafer 25 from the semiconductor element 30.

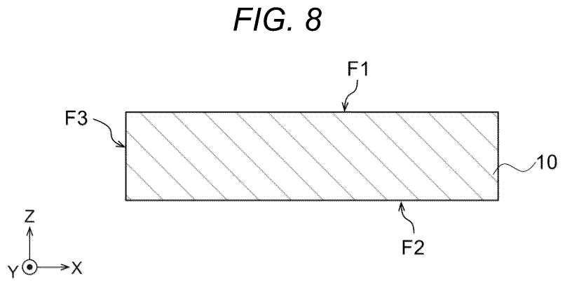

Next, as illustrated in FIG. 8, the silicon film 20 is selectively removed from the removed semiconductor wafer 25 using wet etching.

The wafer main body 10 can be reused for the semiconductor wafer 25. For example, as illustrated in FIG. 1 and FIG. 2, the semiconductor wafer 25 can be formed again by forming the silicon film 20 again at the front surface of the wafer main body 10. At this time, preferably, the silicon film 20 is provided at the first surface, the second surface, and the side surface F1 to F3 of the wafer main body 10 to continuously cover the first surface, the second surface, and the side surface F1 to F3. The recycled semiconductor wafer 25 may be used to form the semiconductor element 30 again. Alternatively, the semiconductor wafer 25 may be used to form another semiconductor element.

On the other hand, the semiconductor wafer 50, the semiconductor elements 30 and 60, and the insulation layers 40 and 70 are cut into a plurality of individual semiconductor chips in a dicing process.

In the present embodiment, the semiconductor wafer 25 is separated from the semiconductor element 30. However, the semiconductor wafer 25 may be removed by polishing. In that case, the wafer main body 10 is not reused.

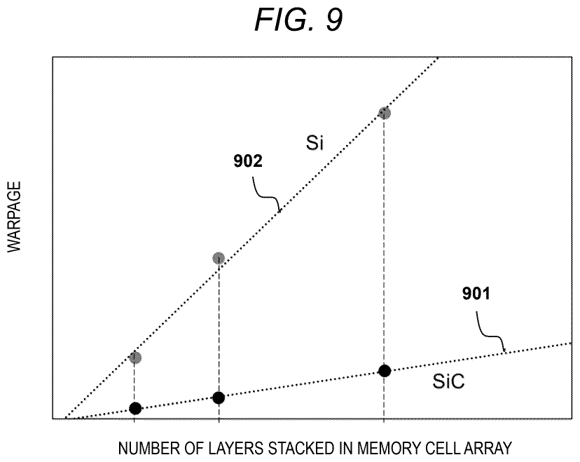

FIG. 9 is a graph showing the relationship between the number of layers stacked in a memory cell array and the amount of warpage of a semiconductor wafer. The horizontal axis of this graph represents the number of layers stacked in the memory cell array. The vertical axis represents the amount of warpage of the semiconductor wafer 25. For example, assuming that the first surface F1 or the second surface F2 is an X-Y orthogonal coordinate plane and a direction perpendicular to the X-Y plane is the Z direction, the amount of warpage of the semiconductor wafer 25 indicates a position (height) of an end portion in the Z direction with respect to the canter of the first surface F1 or the second surface F2. In addition, the amount of warpage indicates the maximum warpage in a manufacturing process of forming the semiconductor element 30 and the insulation layer 40 on the semiconductor wafer 25. Alternatively, the amount of warpage may be the average value of the warpage in the above-described manufacturing process.

For example, a semiconductor wafer formed using silicon may warp in a convex or concave shape in one of the X direction or the Y direction. Or, a semiconductor wafer formed using silicon may warp in convex or concave shape in both the X direction and the Y direction. Or, a semiconductor wafer formed using silicon may warp in a convex shape in one of the X direction and the Y direction and in a concave shape in the other direction.

FIG. 9 shows the amount of warpage when the wafer main body 10 according to the present embodiment is SiC (line 901), and the amount of warpage when a wafer main body is silicon (line 902) as a comparison example.

Referring to the graph of FIG. 9, the amount of warpage increases substantially in proportion to the increase in the number of layers stacked in the memory cell array, regardless of whether the wafer main body 10 is SiC or silicon. However, when the wafer main body 10 is SiC, the amount of warpage of the semiconductor wafer 25 is about 85% less than that of the semiconductor wafer made of silicon. This is because the Young's modulus of SiC is higher than that of silicon.

As described above, according to the present embodiment, the wafer main body 10 is made of a material having a Young's modulus higher than silicon. Thus, even when the semiconductor element 30 and the insulation layer 40 are formed on the semiconductor wafer 25, the amount of warpage of the semiconductor wafer 25 can be made relatively small.

In the semiconductor wafer 25, the first surface, the second surface, and the side surface F1 to F3 of the wafer main body 10 are continuously covered with the silicon film 20. Accordingly, the etching solution can be prevented from entering an interface between the silicon film 20 and the wafer main body 10, and deformation of the silicon film 20 and the wafer main body 10 can be prevented.

Since the silicon film 20 is present on the first surface F1, even when the first surface F1 of the wafer main body 10 has defects, irregularities, or the like, the silicon film 20 can flatten the first surface F1. As a result, the semiconductor element 30 can be easily formed on the first surface F1 side of the semiconductor wafer 25 as designed.

In addition, by providing the silicon film 20 at the second surface F2 of the wafer main body 10, the semiconductor wafer 25 becomes less likely to slip on a stage or a tray during a manufacturing process and transportation. Thus, the position of the semiconductor wafer 25 becomes less likely to be displaced during the manufacturing process. In addition, the semiconductor wafer 25 becomes less likely to fall during conveyance.

Further, the silicon film 20 continuously covers the wafer main body 10, thereby protecting the wafer main body 10. Thus, the wafer main body 10 can be easily reused after the semiconductor wafer 25 is separated from the semiconductor element 30.

Similar to the semiconductor wafer 25, the semiconductor wafer 50 may have a configuration in which the wafer main body 10 is covered with the silicon film 20. In that case, similar to the semiconductor wafer 25 illustrated in FIG. 2, the semiconductor wafer 50 is configured with a wafer main body made of a material having a Young's modulus higher than silicon, and a silicon film formed at least on the side of the wafer main body on which a semiconductor element is to be formed. The wafer main body of the semiconductor wafer 50 is made of a material containing, for example, SiC, Si₃N₄, AlN, Al₂O₃, or diamond. The wafer main body of the semiconductor wafer 50 may be a polycrystalline material. In that case, defects or irregularities in the wafer main body of the semiconductor wafer 50 are covered with the silicon film to be flattened. In addition, preferably, the silicon film continuously covers a front surface (third surface), a back surface (fourth surface) opposite to the front surface, and a side surface located between the front surface and the back surface of the wafer main body of the semiconductor wafer 50. As a result, the same effect as described above can be achieved for the semiconductor wafer 50. However, when semiconductor wafer 50 is not separated from the semiconductor element 60, the semiconductor wafer 50 is not reused.

### Application to Memory Device

Next, a case in which the present embodiment is applied to a memory device will be described.

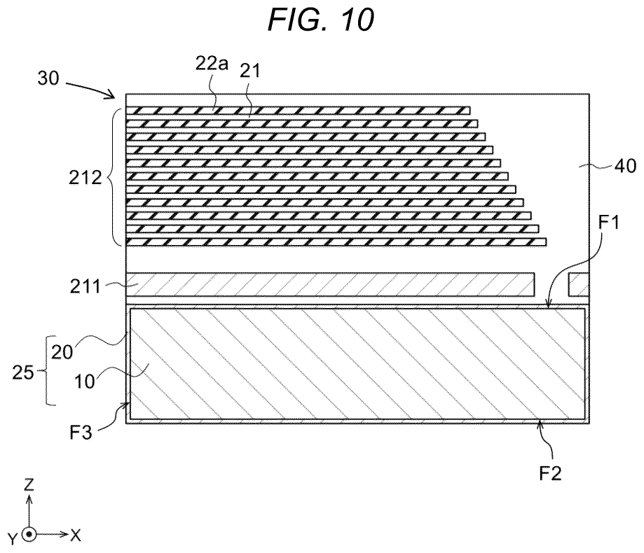

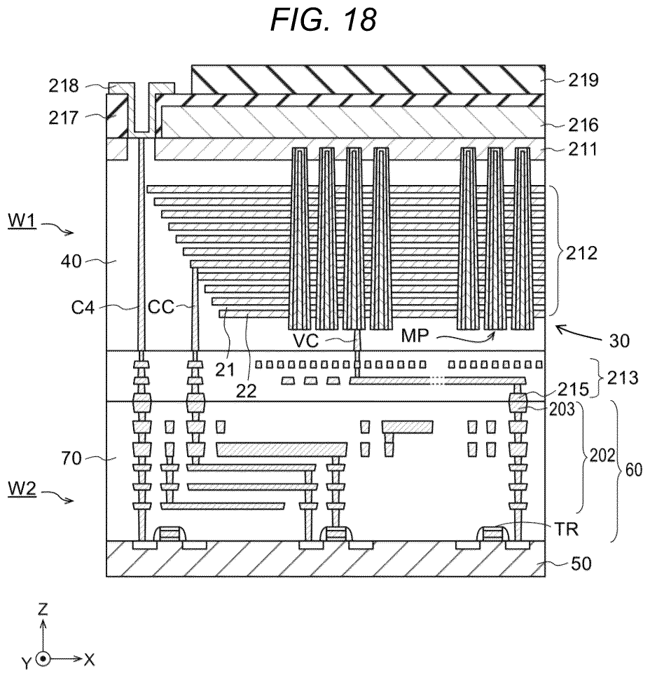

FIG. 10 to FIG. 18 are cross-sectional views illustrating an example of a manufacturing method for a memory device according to the present embodiment.

As illustrated in FIG. 10, a conductive layer 211, a stacked layer portion 212, and a part of the insulation layer 40 are formed above the first surface F1 side of the semiconductor wafer 25. The conductive layer 211 serves as a source layer. The conductive layer 211 is made of, for example, a conductive material such as polysilicon or tungsten.

The stacked layer portion 212 is formed by stacking a plurality of material layers 22a and a plurality of insulation layers 21 in an alternate manner in the Z direction. As the material layer 22a, for example, a silicon nitride film is used. The material layers 22a serve as sacrificial layers that are replaced with the material of electrode layers in a subsequent replacement process. As the insulation layer 21, for example, a silicon oxide film is used.

Lithography and etching techniques are used to form end portions of the material layers 22a of the stacked layer portion 212 in a stepped shape. The stepped portion of the material layers 22a is provided for connecting contact plugs to the electrode layers later.

The insulation layer 40 covers the stacked layer portion 212. As the insulation layer 40, for example, a silicon oxide film is used.

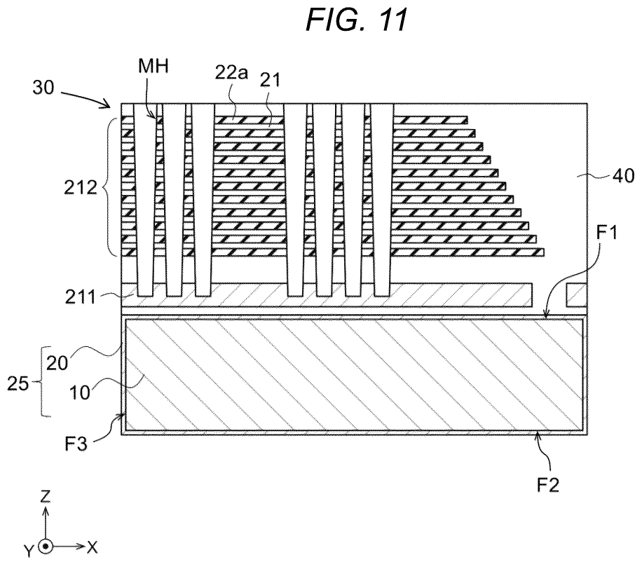

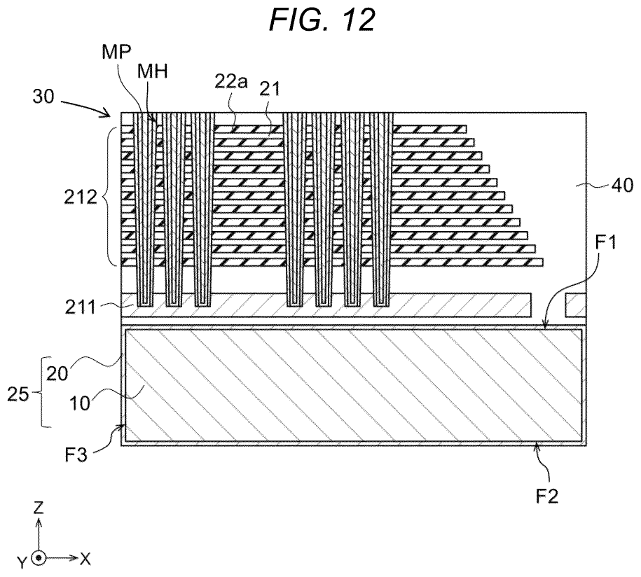

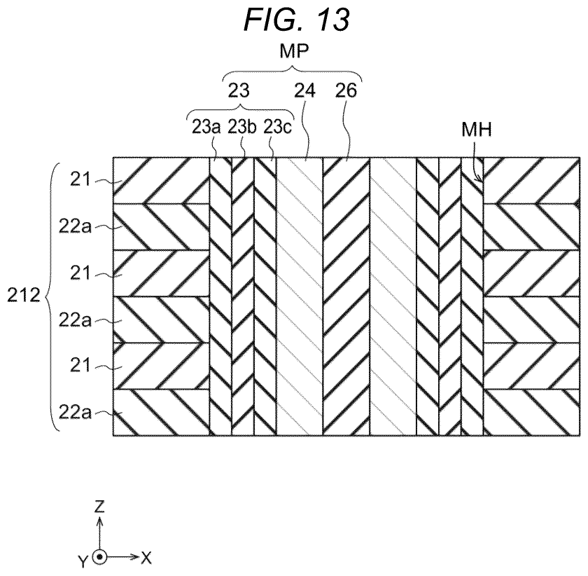

Next, as illustrated in FIG. 11, a plurality of memory holes MH is formed in the stacked layer portion 212 by using lithography and etching techniques. The memory holes MH are formed to penetrate the stacked layer portion 212 in the Z direction to reach the conductive layer 211.

Next, as illustrated in FIG. 12, memory pillars MP are formed inside the memory holes MH. As illustrated in FIG. 13, the memory pillar MP includes a memory film 23, a semiconductor layer 24, and a core layer 26.

The memory film 23 includes a block insulation film 23a, a charge storage film 23b, and a tunnel insulation film 23c. The block insulation film 23a prevents the back tunneling of charge from the electrode layers (word lines) to the charge storage film 23b. As the block insulation film 23a, for example, a silicon oxide film or a metal oxide film (e.g., an aluminum oxide film) is used.

The charge storage film 23b includes a trap site that traps charge in the film. The threshold voltage value of a memory cell varies depending on the presence or absence of charge in the charge storage film 23b or the amount of charge trapped in the charge storage film 23b. This allows the memory cell to retain information. As the charge storage film 23b, for example, a silicon nitride film is used.

The tunnel insulation film 23c is a potential barrier between the semiconductor layer 24 and the charge storage film 23b. For example, when electrons are injected from the semiconductor layer 24 into the charge storage film 23b (write operation), and when positive holes are injected from the semiconductor layer 24 into the charge storage film 23b (erase operation), the electrons and the positive holes respectively pass (tunnel) through the potential barrier of the tunnel insulation film 23c. As the tunnel insulation film 23c, for example, a material containing silicon oxide, or a material containing silicon oxide and silicon nitride is used.

The memory film 23 is formed by depositing the block insulation film 23a, the charge storage film 23b, and the tunnel insulation film 23c at the inner wall of the memory hole MH in this order.

The semiconductor layer 24 is formed inside the memory film 23 in the memory hole MH. As the semiconductor layer 24, for example, a semiconductor material such as silicon is used. For example, amorphous silicon is deposited at the inner wall of the tunnel insulation film 23c of the memory film 23. Next, the amorphous silicon is crystallized by heat treatment. As a result, the semiconductor layer 24 becomes a silicon film containing polysilicon or monocrystal silicon.

Here, when the amorphous silicon is deposited in the plurality of memory holes MH, the amorphous silicon applies a stress to the semiconductor wafer 25 in a tensile direction in the X-Y plane of FIG. 13. On the other hand, when the amorphous silicon deposited in the plurality of memory holes MH is crystallized by heat treatment, the polysilicon or the monocrystal silicon applies a stress to the semiconductor wafer 25 in a compression direction in the X-Y plane. In the manufacturing process of the memory device, the process of forming the semiconductor layer 24 is a process in which a particularly large stress is applied to the semiconductor wafer 25. Thus, the amount of warpage often becomes the maximum in the process of forming the semiconductor layer 24.

However, according to the present embodiment, the wafer main body 10 is made of a material having a Young's modulus higher than silicon. Thus, even in the process of forming the semiconductor layer 24, the amount of warpage of the semiconductor wafer 25 is reduced to be small.

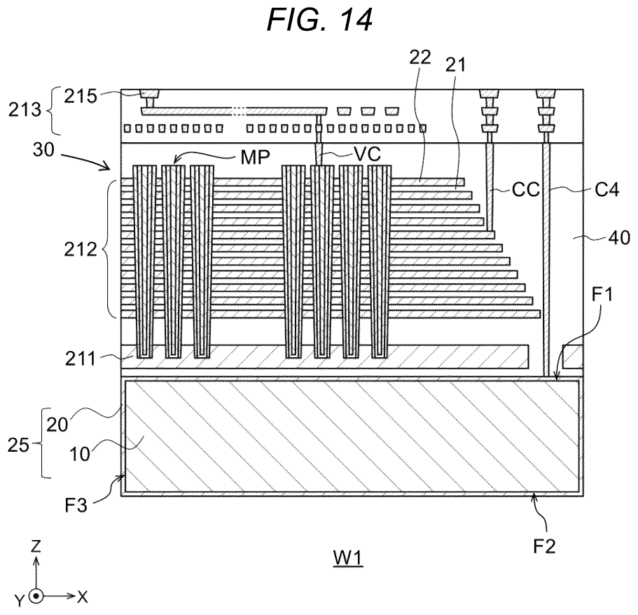

Next, although not illustrated, a slit that penetrates the stacked layer portion 212 in the Z direction and reaches the conductive layer 211 is formed using lithography and etching techniques. Then, the material layers 22a are removed via the slit. Then, the material of electrode layers 22 is embedded in the spaces left after the removal of the material layers 22a, via the slit. As the material of the electrode layers 22, for example, a conductive material such as tungsten is used. In this way, the material layers 22a are replaced with the electrode layers 22 as illustrated in FIG. 14 (replacement process).

After that, in the stepped portion of the stacked layer portion 212, a contact plug CC to be connected to each electrode layer 22 is formed. A contact plug C4 that reaches the semiconductor wafer 25 is formed outside the stacked layer portion 212.

A via contact VC to be connected to the semiconductor layer 24 of the memory pillar MP is formed, and a multilayer wiring layer 213 including bit lines is formed. The uppermost layer of the multilayer wiring layer 213 is formed such that the wiring 215 is exposed from the front surface of a portion of the insulation layer 40 in the multilayer wiring layer 213. The wiring 215 is electrically connected to any part of the memory cell array.

Accordingly, a semiconductor structure (hereinafter, also referred to as an array structure) W1 on the memory cell array side illustrated in FIG. 14 is formed.

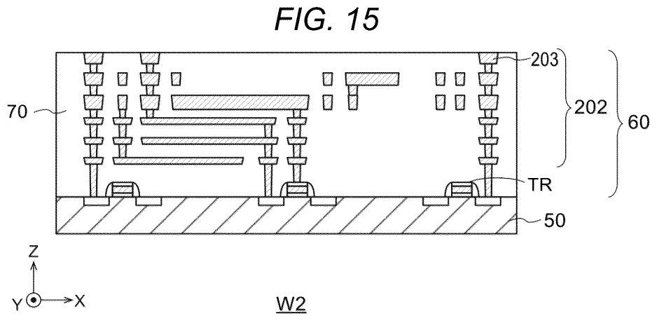

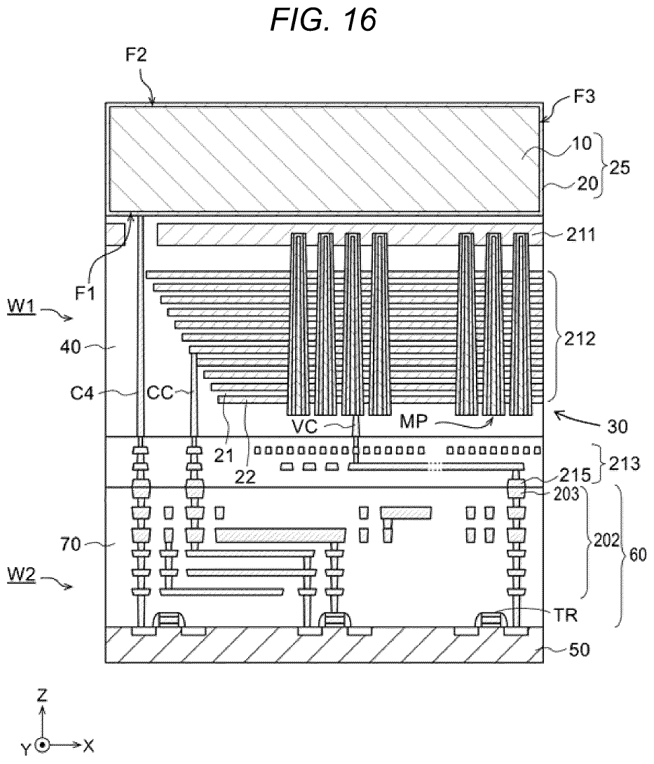

On the other hand, separately from the array structure W1, a plurality of transistors TR constituting a CMOS circuit is formed as the semiconductor element 60 on the semiconductor wafer 50 as illustrated in FIG. 15.

Next, the insulation layer 70 is formed on the semiconductor wafer 50 to cover the plurality of transistors TR. As the insulation layer 70, for example, a silicon oxide film is used.

In addition, contact plugs or wirings connected to the transistors TR are formed as appropriate inside the insulation layer 70. As a result, a multilayer wiring layer 202 is formed.

In the uppermost layer of the multilayer wiring layer 202, a wiring 203 is formed to be exposed from the front surface of the insulation layer 70. The wiring 203 is electrically connected to any part of the CMOS circuit.

Accordingly, a semiconductor structure (hereinafter, also referred to as a CMOS structure) W2 on the CMOS side is formed.

Next, as illustrated in FIG. 16, the array structure W1 and the CMOS structure W2 are bonded together. At this time, the semiconductor element 30 of the array structure W1 and the semiconductor element 60 of the CMOS structure W2 are opposed to each other and the insulation layer 40 and the insulation layer 70 are bonded together. Accordingly, the wiring 215 and the wiring 203 are brought into direct contact with each other to be electrically connected to each other.

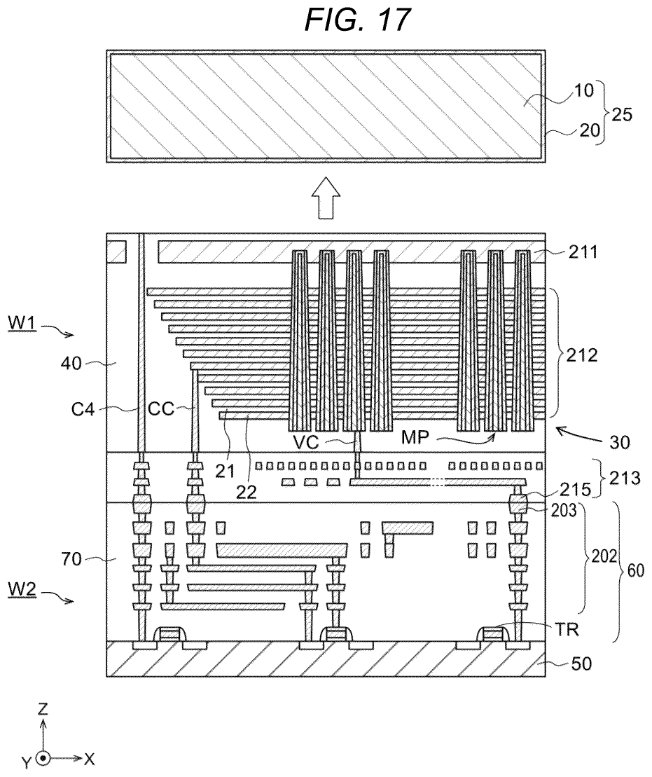

Next, as illustrated in FIG. 17, the semiconductor wafer 25 is separated. As described above, the semiconductor wafer 25 may be separated using any of wet etching, a laser separation method, a separation method using a blade, or a separation method using waterjet.

Next, the conductive layer 211 is exposed at the front surface of the array structure W1 after the semiconductor wafer 25 is separated, and a conductive layer 216 is formed on the conductive layer 211. As the conductive layer 216, for example, a low resistance metal material such as copper or tungsten is used.

Next, an interlayer insulation film 217 is formed on the conductive layer 216. As the interlayer insulation film 217, for example, a silicon oxide film is used.

Next, lithography and etching techniques are used to remove the interlayer insulation film 217 on the contact plug C4. An electrode pad 218 electrically connected to the contact plug C4 is formed on the contact plug C4. As the electrode pad 218, for example, a low resistance metal material such as copper or tungsten is used.

Next, a passivation layer 219 is formed on the interlayer insulation film 217. As the passivation layer 219, for example, an insulation material such as a polyimide is used.

Then, the array structure W1 and the CMOS structure W2 which are bonded together are cut into a plurality of semiconductor chips by dicing. As a result, the memory device according to the present embodiment is completed.

On the other hand, the semiconductor wafer 25 after separation is treated with wet etching as described with reference to FIG. 8 to selectively remove the silicon film 20, and then reused as the wafer main body 10.

As described above, the present embodiment can be applied to a manufacturing method for the memory device. Therefore, the warpage of the semiconductor wafer 25 can be reduced and the above-described effect of the present embodiment can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, the method comprising:
forming a first semiconductor wafer including a first wafer main body and a first silicon film, the first wafer main body including a first surface, a second surface located opposite to the first surface, and a side surface located between the first surface and the second surface, the first wafer main body having a Young's modulus higher than silicon, the first silicon film being formed at the first surface, the second surface, and the side surface of the first wafer main body;
forming a first circuit on the first surface of the first semiconductor wafer;
forming a first insulation layer covering the first circuit on the first surface of the first semiconductor wafer;
forming a second circuit on a second semiconductor wafer;
forming a second insulation layer covering the second circuit on the second semiconductor wafer;
bonding the first insulation layer and the second insulation layer after causing the first circuit and the second circuit to be opposed to each other; and
removing the first semiconductor wafer after the bonding of the first insulation layer and the second insulation layer.

2. The method for manufacturing a semiconductor device according to claim 1, wherein the first wafer main body comprises at least one of SiC, Si₃N₄, AlN, Al₂O₃, or diamond.

3. The method for manufacturing a semiconductor device according to claim 1, wherein the first wafer main body comprises a polycrystalline material.

4. The method for manufacturing a semiconductor device according to claim 1, wherein the first silicon film continuously covers the first surface, the second surface, and the side surface of the first wafer main body.

5. The method for manufacturing a semiconductor device according to claim 4, wherein the first silicon film is formed at the first surface, the second surface, and the side surface of the first wafer main body without exposing the first wafer main body from the first silicon film.

6. The method for manufacturing a semiconductor device according to claim 1, wherein the first semiconductor wafer is removed using a wet etching method, a laser separation method, a separation method using a blade, or a separation method using waterjet.

7. The method for manufacturing a semiconductor device according to claim 1, further comprising: after the removing of the first semiconductor wafer,
removing the first silicon film from the first semiconductor wafer, and
forming the first semiconductor wafer again by forming a second silicon film at the first surface, the second surface, and the side surface of the first wafer main body.

8. The method for manufacturing a semiconductor device according to claim 7, wherein the second silicon film continuously covers the first surface, the second surface, and the side surface of the first wafer main body.

9. The method for manufacturing a semiconductor according to claim 7, wherein the first silicon film is removed from the first semiconductor wafer by a wet etching method.

10. The method for manufacturing a semiconductor device according to claim 1, further comprising: after the removing of the first semiconductor wafer, cutting the first circuit, the second circuit, and the second semiconductor wafer into a plurality of semiconductor chips.

11. The method for manufacturing a semiconductor device according to claim 1, wherein the first circuit includes a memory cell array.

12. The method for manufacturing a semiconductor device according to claim 1, wherein the second circuit includes a complementary metal oxide semiconductor (CMOS) circuit.

13. The method for manufacturing a semiconductor device according to claim 1, wherein
the forming of the first circuit comprises:
forming a stacked layer portion by stacking, above the first semiconductor wafer, a plurality of material layers and a plurality of insulation layers in an alternate manner in a first direction,
forming a plurality of holes penetrating the stacked layer portion in the first direction,
depositing a semiconductor layer inside a memory film in the plurality of holes, and
crystallizing the semiconductor layer.

14. The method for manufacturing a semiconductor device according to claim 13, wherein the semiconductor layer is crystallized into polysilicon or monocrystal silicon by heat-treating amorphous silicon deposited inside the memory film.

15. The method for manufacturing a semiconductor device according to claim 13, wherein
the forming of the first circuit further comprises: after the crystallizing of the semiconductor layer,
removing the plurality of material layers, and
forming a plurality of electrode layers by embedding a conductive material into spaces left after the removing of the plurality of material layers.

16. The method for manufacturing a semiconductor device according to claim 1, further comprising:
exposing, from the first insulation layer, a first wiring electrically connected to the first circuit; and
exposing, from the second insulation layer, a second wiring electrically connected to the second circuit,
wherein, in the bonding of the first insulation layer and the second insulation layer, the first wiring and the second wiring are brought into contact with each other.

17. The method for manufacturing a semiconductor device according to claim 1, wherein the second semiconductor wafer includes a second wafer main body having a Young's modulus higher than silicon, and a third silicon film formed at a third surface of the second wafer main body.

18. The method for manufacturing a semiconductor device according to claim 17, wherein the second wafer main body comprises at least one of SiC, Si₃N₄, AlN, Al₂O₃, or diamond.

19. The method for manufacturing a semiconductor device according to claim 17, wherein the second wafer main body comprises a polycrystalline material.

20. The method for manufacturing a semiconductor device according to claim 17, wherein the third silicon film is formed at the third surface, a fourth surface opposite to the third surface, and a side surface located between the third surface and the fourth surface of the second wafer main body.
